(19) United States
(12) Patent Application Publication
(10) Pub. No.: US 2016/0155975 A1
(43) Pub. Date: Jun. 2, 2016

(54) ORGANIC PHOTOELECTRONIC DEVICE AND IMAGE SENSOR

(71) Applicant: Samsung Electronics Co., Ltd., Suwon-si (KR)

(72) Inventors: Yong Wan JIN, Seoul (KR); Gae Hwang LEE, Seongnam-si (KR); Seon-Jeong LIM, Yongin-si (KR)

(21) Appl. No.: 14/696,091

(22) Filed: Apr. 24, 2015

(30) Foreign Application Priority Data
Dec. 1, 2014 (KR) 10-2014-0169675

(51) Int. Cl. H01L 51/44; H01L 27/30

(52) U.S. Cl. CPC H01L 51/447; H01L 51/442; H01L 51/448; H01L 27/307

(57) ABSTRACT

An organic photoelectronic device includes a first light-transmitting electrode, a second light-transmitting electrode opposite to the first light-transmitting electrode, an active layer between the first light-transmitting electrode and the second light-transmitting electrode, and a UV blocking layer on the first light-transmitting electrode, where the UV blocking layer includes at least one of a UV light absorbing layer and a UV reflecting layer, the UV light absorbing layer includes a layer including an organic material, and the UV reflecting layer includes a plurality of layers, where each of the plurality of layers includes an organic material, an inorganic material, an organic or a combination thereof.

### CROSS-REFERENCE TO RELATED APPLICATION

This application claims priority to Korean Patent Application No. 10-2014-0169675 filed on Dec. 1, 2014, and all the benefits accruing therefrom under 35 U.S.C. §119, the content of which in its entirety is herein incorporated by reference.

### BACKGROUND

1. Field

Embodiments of the invention relate to an organic photoelectronic device and an image sensor including the organic photoelectronic device.

2. Description of the Related Art

A photoelectronic device converts light into an electrical signal using photoelectronic effects, and may include a photodiode, a phototransistor, and the like, and may be applied to an image sensor, a solar cell, and the like.

An image sensor including a photodiode is desired to have high resolution and thus a small pixel. At present, silicon photodiodes are widely used, but present a problem of deteriorated sensitivity because of a small absorption area due to small pixels. Accordingly, an organic material that is capable of replacing silicon has been researched.

The organic material has a high extinction coefficient and selectively absorbs light in a particular wavelength region depending on a molecular structure, and thus may simultaneously replace a photodiode and a color filter and resultantly improve sensitivity and contribute to high integration.

The organic material in an active layer of a photodiode is ready to be involved in a chemical reaction such as oxidation/reduction, with water or oxygen in the air. Accordingly, a research of introducing a protecting layer to protect a diode from the contaminants, such as water, oxygen, and the like in the air, has been performed.

### SUMMARY

When fabricating an image sensor including an organic photoelectronic device, ultraviolet light is typically radiated to the top of the image sensor in a process of forming a micro lens and the like. In this case, the organic active layer in the organic photoelectronic device may be damaged by the ultraviolet light radiated, whereby a dark current may increase and characteristics of the image sensor may be deteriorated.

In an exemplary embodiment, an organic photoelectronic device includes an ultraviolet (“UV”) light blocking layer that protects an organic active layer therein.

Exemplary embodiments of the invention relate to an image sensor including the organic photoelectronic device.

According to an exemplary embodiment, an organic photoelectronic device includes a first light-transmitting electrode, a second light-transmitting electrode opposite to the first light-transmitting electrode, an active layer between the first light-transmitting electrode and the second light-transmitting electrode, and a UV blocking layer on the first light-transmitting electrode, where the UV blocking layer includes at least one of a UV light absorbing layer and a UV reflecting layer. In such an embodiment, the UV light absorbing layer includes a layer including an organic material, and the UV reflecting layer includes a plurality of layers, where each of the plurality of layers includes an organic material, an inorganic material or a combination thereof.

In an exemplary embodiment, the UV blocking layer may have a transmittance less than or equal to about 50% with respect to light having a wavelength less than or equal to 380 nanometers (nm).

In an exemplary embodiment, the UV blocking layer may include a UV reflecting layer including a plurality of layers, where each of the plurality of layers may include an inorganic oxide, and inorganic oxides of the plurality of layers may be different from each other.

In an exemplary embodiment, the inorganic oxide of each of the plurality of layers may have different refractive indices from each other, and thicknesses of the plurality of layers are determined to allow the UV reflecting layer to have a transmittance greater than or equal to about 50% with respect to light having a wavelength less than or equal to about 380 nm.

In an exemplary embodiment, the inorganic oxide may have a refractive index in a range of about 1.4 to about 2.1.

In an exemplary embodiment, when the inorganic oxide of a layer of the plurality of layers has a refractive index of greater than or equal to about 1.7 and less than or equal to about 2.1, the layer may have a thickness in a range of about 10 nm to about 100 nm.

In an exemplary embodiment, when the inorganic oxide of the layer has a refractive index of greater than or equal to about 1.4 and less than about 1.7, the layer may have a thickness in a range of about 10 nm to about 100 nm.

In an exemplary embodiment, the inorganic material, which reflects UV light, may include ZrO₂, TiO₂, ZnS, SiO₂, SiON, Al₂O₃ or a combination thereof.

In an exemplary embodiment, the organic material, which absorbs UV light, may include an organic compound having a UV extinction coefficient of greater than or equal to about 0.2.

In an exemplary embodiment, the organic material that absorbs UV light may include at least one of stilbene derivatives, phenylenevinylene derivatives, bezoxazole derivatives, bezotriazole derivatives, benzophenone derivatives and triazine derivatives.

In an exemplary embodiment, the organic photoelectronic device may further include a thin film encapsulator on the UV blocking layer or between the UV blocking layer and the first light-transmitting electrode.

In an exemplary embodiment, each of the first light-transmitting electrode and the second light-transmitting electrode may independently include at least one of indium tin oxide (“ITO”), indium zinc oxide (“IZO”), tin oxide (SnO), aluminum tin oxide (“ATO”), aluminum zinc oxide (“AZO”), and fluorine-doped tin oxide (“FTO”).

In an exemplary embodiment, the first light-transmitting electrode may have a thickness in a range of about 1 nm to about 100 nm.

In an exemplary embodiment, the second light-transmitting electrode may have a thickness in a range of about 1 nm to about 200 nm.

In an exemplary embodiment, the active layer may selectively absorb light in a green wavelength region.

In an exemplary embodiment, the active layer may include a p-type semiconductor material having a maximum absorption peak in a wavelength region of about 500 nm to about 600 nm, and an n-type semiconductor material having a maximum absorption peak in the wavelength region of about 500 nm to about 600 nm.

According to another exemplary embodiment, an image sensor including the organic photoelectronic device described above is provided.

In an exemplary embodiment, the image sensor may further include a micro lens on the UV blocking layer of the organic photoelectronic device.

According to another exemplary embodiment, an image sensor includes: a green pixel including the organic photoelectronic device described above and a green photo-sensing device electrically connected to the organic photoelectronic device; a red pixel including a red color filter and a red photo-sensing silicon photodiode; and a blue pixel including a blue color filter and a blue photo-sensing silicon diode. In such an embodiment, the red photo-sensing silicon diode and the blue photo-sensing silicon diode are integrated in a semiconductor substrate disposed below the green pixel, and the red color filter and the blue color filter are disposed between the semiconductor substrate and the green pixel, and to correspond to positions of the red photo-sensing silicon diode and the blue photo-sensing silicon diode, respectively.

In an exemplary embodiment, the image sensor may further include a micro lens disposed on the green pixel.

According to another exemplary embodiment, an image sensor includes: a green pixel including the organic photoelectronic device described above and a green photo-sensing device electrically connected to the organic photoelectronic device; a red pixel including a red photo-sensing silicon photodiode; and a blue pixel including a blue photo-sensing silicon diode. In such an embodiment, the red photo-sensing silicon diode and the blue photo-sensing silicon diode are integrated in a semiconductor substrate disposed below the green pixel, and the red photo-sensing silicon diode is disposed below the blue photo-sensing silicon diode.

In an exemplary embodiment, the image sensor may further include a micro lens disposed on the green pixel.

### BRIEF DESCRIPTION OF THE DRAWINGS

These and/or other features of the invention will become apparent and more readily appreciated from the following detailed description of embodiments thereof, taken in conjunction with the accompanying drawings, in which:

FIG. 1 is a cross-sectional view of an exemplary embodiment of an organic photoelectronic device according to the invention;

FIG. 2 is a cross-sectional view of an alternative exemplary embodiment of an organic photoelectronic device according to the invention;

FIG. 3 is a cross-sectional view of another alternative exemplary embodiment of an organic photoelectronic device according to the invention;

FIG. 4 is a cross-sectional view of an exemplary embodiment of an organic complementary metal-oxide-semiconductor (“CMOS”) image sensor according to the invention,

FIG. 5 is a cross-sectional view of an alternative exemplary embodiment of an organic CMOS image sensor according to the invention;

FIG. 6 is a cross-sectional view of another alternative exemplary embodiment of an organic CMOS image sensor according to the invention;

FIG. 7 is a cross-sectional view of yet another alternative exemplary embodiment of an organic CMOS image sensor according to the invention;

FIG. 8 is a cross-sectional view of still another alternative exemplary embodiment of an organic CMOS image sensor according to the invention;

FIG. 9 is simulation graphs showing light transmittances versus wavelengths in a range of 300 nanometers (nm) to 700 nm of the UV reflecting layers prepared in Example 1 by alternately disposing two inorganic oxide layers having different refractive indexes, changing number of layers and thickness of each layer;

FIG. 10 is a graph showing light transmittance versus wavelengths of a UV blocking layer prepared by depositing a ultraviolet (“UV”) light absorbing material, 4,4-Bis(2-benzoxazolyl)stilbene in a thickness of 125 nm;

FIG. 11 is graphs showing external quantum efficiency (“EQE”) versus wavelengths of the organic photoelectronic devices according to the Reference and Examples 1 and 2; and

FIG. 12 is graphs showing light transmittances versus wavelengths of the organic photoelectronic devices according to the Reference and Examples 2 and 3.

### DETAILED DESCRIPTION

The invention now will be described more fully hereinafter with reference to the accompanying drawings, in which various embodiments are shown. This invention may, however, be embodied in many different forms, and should not be construed as limited to the embodiments set forth herein. Rather, these embodiments are provided so that this disclosure will be thorough and complete, and will fully convey the scope of the invention to those skilled in the art. Like reference numerals refer to like elements throughout.

As used herein, when a definition is not otherwise provided, the term “substituted” refers to one substituted with a substituent selected from a halogenatom (F, Br, Cl, or I), a hydroxy group, an alkoxy group, a nitro group, a cyano group, an amino group, an azido group, an amidino group, hydrazino group, a hydrazono group, a carbonyl group, a carbamyl group, a thiol group, an ester group, a carboxyl group or a salt thereof, a sulfonic acid group or a salt thereof, phosphoric acid or a salt thereof, a C1 to C20 alkyl group, a C2 to C20 alkenyl group, a C2 to C20 alkynyl group, a C6 to C30 aryl group, a C7 to C30 arylalkyl group, a C1 to C4 alkoxy group, a C1 to C20 heteroalkyl group, a C3 to C20 heteroarylalkyl group, a C3 to C30 cycloalkyl group, a C3 to C15 cycloalkenyl group, a C6 to C15 cycloalkynyl group, a C2 to C20 heterocycloalkyl group, and a combination thereof, instead of hydrogen of a compound.

As used herein, when specific definition is not otherwise provided, the term “hetero” refers to one including 1 to 3 heteroatoms selected from N, O, S, and P.

In the drawings, the thickness of layers, films, panels, regions, etc., are exaggerated for clarity. Like reference numerals designate like elements throughout the specification.

It will be understood that when an element is referred to as being “on,” “connected” or “coupled” to another element, it can be directly on, connected or coupled to the other element or intervening elements may be present. In contrast, when an element is referred to as being “directly on,” “directly connected” or “directly coupled” to another element, there are no intervening elements present. As used herein the term “and/or” includes any and all combinations of one or more of the associated listed items. Further, it will be understood that when a layer is referred to as being “under” another layer, it can be directly under or one or more intervening layers may also be present. In addition, it will also be understood that when a layer is referred to as being “between” two layers, it can be the only layer between the two layers, or one or more intervening layers may also be present.

It will be understood that, although the terms “first”, “second”, etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, a first element, component, region, layer or section discussed below could be termed a second element, component, region, layer or section without departing from the teachings of example embodiments.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the example term “below” can encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting of example embodiments. As used herein, the singular forms “a,” “an” and “the” are intended to include the plural forms as well, unless the context clearly indicates otherwise. “Or” means “and/or.” As used herein, the term “and/or” includes any and all combinations of one or more of the associated listed items. It will be further understood that the terms “comprises” and/or “comprising,” or “includes” and/or “including” when used in this specification, specify the presence of stated features, integers, steps, operations, elements, and/or components, but do not preclude the presence or addition of one or more other features, integers, steps, operations, elements, components, and/or groups thereof.

Exemplary embodiments are described herein with reference to cross-sectional illustrations that are schematic illustrations of idealized embodiments (and intermediate structures). As such, variations from the shapes of the illustrations as a result, for example, of manufacturing techniques and/or tolerances, are to be expected. Thus, example embodiments should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of example embodiments.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” can mean within one or more standard deviations, or within ±30%, 20%, 10%, 5% of the stated value.

Unless otherwise defined, all terms (including technical and scientific terms) used herein have the same meaning as commonly understood by one of ordinary skill in the art to which example embodiments belong. It will be further understood that terms, such as those defined in commonly-used dictionaries, should be interpreted as having a meaning that is consistent with their meaning in the context of the relevant art and will not be interpreted in an idealized or overly formal sense unless expressly so defined herein. As used herein, expressions such as “at least one of,” when preceding a list of elements, modify the entire list of elements and do not modify the individual elements of the list. Although corresponding plan views and/or perspective views of some cross-sectional view(s) may not be shown, the cross-sectional view(s) of device structures illustrated herein provide support for a plurality of device structures that extend along two different directions as would be illustrated in a plan view, and/or in three different directions as would be illustrated in a perspective view. The two different directions may or may not be orthogonal to each other. The three different directions may include a third direction that may be orthogonal to the two different directions. The plurality of device structures may be integrated in a same electronic device. For example, when a device structure (e.g., a memory cell structure or a transistor structure) is illustrated in a cross-sectional view, an electronic device may include a plurality of the device structures (e.g., memory cell structures or transistor structures), as would be illustrated by a plan view of the electronic device. The plurality of device structures may be arranged in an array and/or in a two-dimensional pattern.

Reference will now be made in detail to embodiments, examples of which are illustrated in the accompanying drawings, wherein like reference numerals refer to the like elements throughout. In this regard, the present embodiments may have different forms and should not be construed as being limited to the descriptions set forth herein. Accordingly, the embodiments are merely described below, by referring to the figures, to explain example embodiments of the present description.

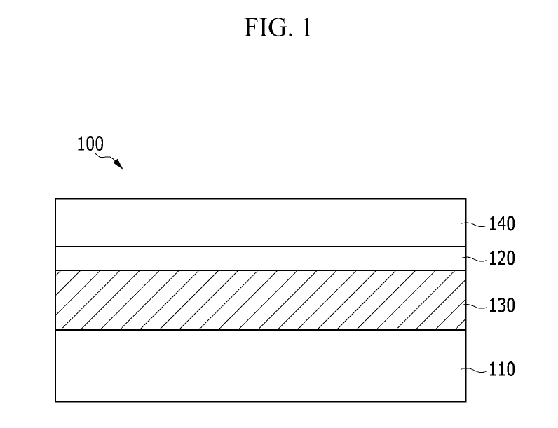

Hereinafter, an exemplary embodiment of an organic photoelectronic device according to the invention will be described in detail referring to FIG. 1.

FIG. 1 is a cross-sectional view showing an exemplary embodiment of an organic photoelectronic device according to the invention.

Referring to FIG. 1, an exemplary embodiment of an organic photoelectronic device 100 according to invention includes a first light-transmitting electrode 120, a second light-transmitting electrode 110 disposed opposite to, e.g., facing, the first light-transmitting electrode 120, an active layer 130 disposed between the first light-transmitting electrode 120 and a second light-transmitting electrode 110 and including an organic light-absorbing material, and a ultraviolet (“UV”) blocking layer 140 disposed on, e.g., above, the first light-transmitting electrode 120. Herein, UV means ultraviolet.

According to an exemplary embodiment, the first light-transmitting electrode 120 may define a front side electrode disposed at a light-incident side, and the second light-transmitting electrode 110 may define a back side electrode dispose at a side opposing to the light-incident side. In such an embodiment, one of the first light-transmitting electrode 120 and the second light-transmitting electrode 110 is an anode, and the other of the first light-transmitting electrode 120 and the second light-transmitting electrode 110 is a cathode.

The UV blocking layer 140 is disposed above the first light-transmitting electrode 120 at a light-incident side and protects the active layer 130 disposed below the first light-transmitting electrode 120 from the incident light, for example, UV light. UV light includes the UV light radiated from the air, as well as the UV light radiated, for example, in an open process of an electrode pad and/or a micro lens forming process in fabricating an image sensor. That is, the UV blocking layer 140 may protect the active layer 130 from UV light radiated in the fabrication process or in use after fabrication.

In one exemplary embodiment, for example, a transmittance of UV light having a wavelength less than or equal to about 380 nanometers (nm) through the UV blocking layer 140 may be equal to or less than about 50%.

In one exemplary embodiment, for example, the UV blocking layer 140 may be a UV absorbing layer, that is, a layer that absorbs UV light incident thereto. The UV absorbing layer may include an organic compound having a high UV light extinction coefficient, for example, a UV light extinction coefficient of greater than or equal to about 0.2.

The organic compound having a high UV extinction coefficient may be at least one selected from those known in the art. In one exemplary embodiment, for example, the organic compound having a high UV light extinction coefficient may be at least one selected from compounds used as an optical brightener or a fluorescent whitening agent.

In such an embodiment, the optical brightener and the fluorescent whitening agent may be a colorless or very pale close to colorless organic compound that absorb UV light in the wavelength range of about 300 nm to about 430 nm and re-emits the absorbed light in a wavelength range of about 400 nm to about 500 nm. Such a compound may include at least one of stilbene derivatives, phenylenevinylene derivatives, bezoxazole derivatives, bezotriazole derivatives, benzophenone derivatives, triazine derivatives and the like, but is not limited thereto.

In such an embodiment, for example, the stilbene derivatives may include distyrylbenzene, distyrylbiphenyl, divinylstilbene, coumarin, triazinylaminiostilbene, 4,4′-bis(2-benzoxazolyl)stilbene and the like, but are not limited thereto.

In such an embodiment, for example, phenylenevinylene derivatives or benzoxazole derivatives may include stilbenylbenzoxazole, bis(benzoxazole), benzimidazole, pyrazoline, for example, 1,3-diphenyl-2-pyrazoline and the like, but is not limited thereto.

In such an embodiment, for example, the benzotriazole derivatives may include 2-(2′-Hydroxyphenyl)benzotriazoles, for example, 2-(2′-hydroxy-5′-methylphenyl)-benzotriazole, 2-(3′,5′-di-tert-butyl-2′-hydroxyphenyl)benzotriazole, 2-(5′-tert-butyl-2′-hydroxyphenyl)benzotriazole, 2-(2′-hydroxy-5′-(1,1,3,3-tetramethylbutyl)phenyl)benzotriazole, 2-(3′,5′-di-tert-butyl-2′-hydroxyphenyI)-5-chloro-benzotriazole, 2-(3′-tert-butyl-2′-hydroxy-5′-methylphenyl)-5-chloro-benzotriazole, 2-(3′-sec-butyl-5′-tert-butyl-2′-hydroxyphenyl)benzotriazole, 2-(2′-hydroxy-4′-octyloxyphenyl)benzotriazole, 2-(3′,5′-di-tert-amyl-2′ -hydroxyphenyl)benzotriazole, 2-(3′,5′-bis-[alpha],[alpha]-dimethylbenzyl)-2′-hydroxyphenyl)benzotriazole, 2-(3′-tert-butyl-2′-hydroxy-5′ -(2-octyloxycarbonylethyl)phenyl)-5-chloro-benzotriazole, 2-(3′-tert-butyl-5′-[2-(2-ethylhexyl-oxy)-carbonylethyl]-2′-hydroxyphenyl)-5-chloro-benzotriazole, 2-(3′-tert-butyl-2′-hydroxy-5′-(2-methoxycarbonylethyl)phenyl)-5-chloro-benzotriazole, 2-(3′-tert-butyl-2′-hydroxy-5′-(2-methoxycarbonylethyl)phenyl)benzotriazole, 2-(3′-tert-butyl-2′-hydroxy-5′-(2-octyloxycarbonylethyl)phenyl)benzotriazole, 2-(3′-tert-butyl-5′-[2-(2-ethylhexyloxy)carbonylethyl]-2′-hydroxyphenyl)benzotriazole, 2-(3′-dodecyl-2′-hydroxy-5′-methylphenyl)benzotriazole, 2-(3′-tert-butyl-2′-hydroxy-5′-(2-isooctyloxycarbonylethyl)phenylbenzotriazole, 2,2′-methylene-bis[4-(1,1,3,3-tetramethylbutyl)-6-benzotriazole-2-ylphenol]; the transesterification product of 2-[3′-tert-butyl-5′ -(2-methoxycarbonylethyl)-2′-hydroxyphenyl]-2H-benzotriazole with polyethylene glycol 300; [R—CH₂CH₂—COO—CH₂CH₂—]—₂ where R is 3′-tert-butyl-4′-hydroxy-5′-2H-benzotriazol-2-ylphenyl, 2-[2′-hydroxy-3′-[alpha],[alpha]-dimethylbenzyl)-5′-(1,1,3,3-tetramethylbutyl)-phenyl]benzotriazole; 2-[2′-hydroxy-3′-(1,1,3,3-tetramethylbutyl)-5′-[alpha],[alpha]-dimethylbenzyl)-phenyl]benzotriazole and the like, but are not limited thereto.

In such an embodiment, for example, the benzophenone derivatives may include 2,4-dihydroxy benzophenone, 2,2′4,4′-tetrahydroxy benzophenone, 2-hydroxy-2-methoxy benzophenone, 2-hydroxy-4-methoxy benzophenone-5-sulfonic acid, 2,2′-dihydroxy-4,4′-dimethoxybenzophenone, 2-hydroxy-4-n-octyloxybenzophenone and the like, but are not limited thereto.

In such an embodiment, for example, the triazine and other derivatives may include 2,4-di-tert-butylphenyl-3,5-di-tert-butyl-4-hydroxybenzoate, ethyl-2-cyano-3,3-diphenylacrylate, 2-ethylhexyl-2-cyano-3,3-diphenylacrylate, 2,2-(1,4-phenylene)bis((4H)-3,1-benzoxazone-4-one), 2-[4,6-bis(2,4-dimethylphenyl)-13,5-triazaine-2-yl]-5-(octyloxy)phenol, 2[4,6-bis(2,4-dimethylphenyl)-1,3,5-tirazine-2-yl]-5-(octyloxy)phenol in xylene of 60% to 65%, 2,-ethyl-2′-ethoxy-oxalanylide and the like, and are not limited thereto.

In an exemplary embodiment, the UV absorbing layer may include a single organic compound having a high UV extinction coefficient or a plurality of organic compounds having a high UV extinction coefficient.

In an exemplary embodiment, the UV absorbing layer may be provided, e.g., formed, by thermally depositing one or more organic compounds having a high UV extinction coefficient in a powdery form or in a solution dissolved in an appropriate organic solvent, on the first light-transmitting electrode 120.

In an exemplary embodiment, the UV absorbing layer may include a single layer or a plurality of layers disposed, e.g., stacked or laminated, one on another. In such an embodiment, each layer includes one or more organic compounds having a high UV extinction coefficient.

In an exemplary embodiment, the UV absorbing layer may have a thickness in a range of about 50 nm to about 500 nm.

In an exemplary embodiment, the UV absorbing layer may absorb UV light from the incident light, and may allow light outside of UV range to enter the active layer 130 through the first light-transmitting electrode.

In an alternative exemplary embodiment, the UV blocking layer 140 may be a UV reflecting layer. In such an embodiment, the UV reflecting layer may include a plurality of layers disposed one on another, and each layer may include an organic material, an inorganic material, or a combination thereof, e.g., each layer includes at least one organic material, at least one inorganic material, or at least one organic material and at least one inorganic material.

The UV reflecting layer may reflect UV light using an optical interference by adjusting the refractive indexes and thicknesses of the plurality of layers thereof.

In one exemplary embodiment, for example, the UV reflecting layer may include a plurality of layers disposed one on another, each layer including an inorganic material. In such an embodiment, each layer of the layers has different refractive index from each other.

In an exemplary embodiment, the thickness of each layer of the plurality of layers disposed one on another may be the same as or different from each other.

In an exemplary embodiment, The UV reflecting layer may be formed by alternatively disposing, e.g., laminating, two different layers, where each layer has a different inorganic material from each other.

In an alternative exemplary embodiment, the UV reflecting layer may include a plurality of layers disposed one on another, and each layer includes an organic material. In such an embodiment, each layer of the plurality of layers may have different refractive index from each other.

In such an embodiment, the thicknesses of the plurality of layers disposed one on another may be the same as or different from each other.

In another alternative exemplary embodiment, the UV reflecting layer may include a first layer including an inorganic material and a second layer including an organic material, and the first and second layers are disposed one on another. In such an embodiment, the first layer including the inorganic material and the second layer including the organic material have different refractive indexes from each other.

In such an embodiment, the thicknesses of the first layer including the organic material and the second layer including the inorganic material are the same as or different from each other.

In yet another alternative exemplary embodiment, the UV reflecting layer may include a first layer including an organic or inorganic material, and a second layer including organic and inorganic materials, where the first and second layers are disposed one on another. In such an embodiment, the first layer including the organic or inorganic material and the second layer including the organic and inorganic materials have different refractive indexes from each other.

In such an embodiment, the thicknesses of the first layer including the organic or inorganic material and the second layer including the organic and inorganic materials are the same as or different from each other.

In an exemplary embodiment, the inorganic material may include an inorganic oxide having a refractive index in a range of about 1.4 to about 2.1.

In an exemplary embodiment, where the refractive index of the inorganic oxide is great than or equal to about 1.7 and less than or equal to about 2.1, the thickness of a layer including the inorganic oxide may be in a range of from about 10 nm to about 100 nm.

In an exemplary embodiment, where the refractive index of the inorganic oxide is great than or equal to about 1.4 and less than about 1.7, the thickness of a layer including the inorganic oxide may be in a range of from about 10 nm to about 100 nm.

The inorganic oxide may include at least one of ZrO₂, TiO₂, ZnS, SiO₂, SiON, TiO₂, or Al₂O₃.

In an exemplary embodiment, the UV reflecting layer may be provided, e.g., formed, by a thermal evaporation method, a sputtering method, or an atomic layer deposition (“ALD”) method.

In one exemplary embodiment, for example, where the UV reflecting layer includes an organic material, a layer of the UV reflecting layer including the organic material may be formed by a heat sputtering.

In one exemplary embodiment, for example, where the UV reflecting layer includes an inorganic material, a layer of the UV reflecting layer including the inorganic material may be formed by a sputtering or ALD method.

The UV absorbing layer or the UV reflecting layer may include a plurality of layers, for example, at least three layers, at least four layers, at least five layers, at least six layers, at least seven layers, at least eight layers, at least nine layers or at least ten layers, disposed one on another.

The thickness of the UV blocking layer 140 may be in a range of about 10 nm to about 500 nm. In an exemplary embodiment, where the UV blocking layer has a thickness in such a range from about 10 nm to about 500 nm, the thickness of the UV blocking layer 140 may be in a range of about 20 nm to about 100 nm. The thickness of the UV blocking layer 140 may be variously modified based on the type of material, number of layers, and/or whether the UV blocking layer 140 includes a UV absorbing layer or a UV reflecting layer. In such an embodiment, the UV blocking layer 140 has a thickness in such a range from about 20 nm to about 100 nm, such that the UV blocking layer 140 may efficiently protect an active layer without deteriorating the external quantum efficiency (“EQE”).

In such embodiments, by adjusting thickness or refractive index of each layer of the UV blocking layer, light transmittance of visible light through the UV blocking layer, as well as reflection of UV light by the UV blocking layer, may be substantially improved or effectively maximized.

The first light-transmitting electrode 120 and the second light-transmitting electrode 110 may include at least one selected from materials used as a light-transmitting electrode for an organic photoelectronic device. The light-transmitting electrode may be prepared from a transparent conductive material, such as, for example, indium tin oxide (“ITO”), indium zinc oxide (“IZO”), zinc oxide (“ZnO), tin oxide (SnO), aluminum tin oxide (“ATO”), aluminum zinc oxide (“AZO”), and fluorine-doped tin oxide (“FTO”), or from a thin metal film or a thin metal doped with metal oxide film having a thickness of several nanometers to tens of nanometers.

The active layer 130 may be a layer where p-type and n-type semiconductor materials form a pn flat junction or a bulk heterojunction. The active layer 130 may have a single layer structure or a multilayer structure. The active layer 130 may receive light entering through the first light-transmitting electrode 120, produce an exciton, and then separate the exciton into a hole and an electron.

In the active layer 130, the hole moves toward the anode, and the electron moves toward the cathode, such that a current flows through the organic photoelectronic device.

In an exemplary embodiment, active layer 130 may include p-type and n-type semiconductor materials, which respectively absorb light of a green wavelength region.

In one exemplary embodiment, for example, the active layer 130 may include p-type semiconductor material having a maximum absorption peak in a wavelength region of about 500 nm to 600 nm, and n-type semiconductor material having a maximum absorption peak in a wavelength region of about 500 nm to 600 nm.

The p-type and n-type semiconductor materials may respectively have a bandgap in a range of about 1.5 electron-volt (eV) to about 3.5 eV, e.g., a bandgap in a range of about 2.0 eV to about 2.5 eV. The p-type and n-type semiconductor materials having a bandgap in such a range may absorb light of a green wavelength region and show a maximum absorption peak specifically in a wavelength region of about 500 nm to about 600 nm.

The p-type and n-type semiconductor materials may have a full width at half maximum (“FWHM”) in a range of about 50 nm to about 150 nm in an absorbance curve. Herein, the FWHM is a width of a wavelength region corresponding to a half of a maximum absorbance point, and a smaller FWHM indicates selective absorbance of light of a narrow wavelength region and high wavelength selectivity. Accordingly, a material having FWHM within such a range of about 50 nm to about 150 nm may have high selectivity for a green wavelength region.

The p-type semiconductor material and the n-type semiconductor material may have a lowest unoccupied molecular orbital (“LUMO”) energy level difference in a range of about 0.2 eV to about 0.7 eV, e.g., in a range of about 0.3 eV to about 0.5 eV. When the p-type semiconductor material and the n-type semiconductor material in the active layer 130 have a LUMO energy level difference within such a range of about 0.2 eV to about 0.7 eV, EQE may be improved and effectively adjusted based on a bias applied thereto.

The p-type semiconductor material may include, for example, a compound such as N,N-dimethyl-quinacridone (“DMQA”) and a derivative thereof, diindenoperylene, dibenzo{[f,f′]-4,4′,7,7′-tetraphenyl}diindeno[1,2,3-cd:1′,2′,3′-lm]perylene, but is not limited thereto.

The n-type semiconductor material may include, for example, a compound such as dicyanovinyl-terthiophene (“DCV3T”) and a derivative thereof, perylenediimide, phthalocyanine and a derivative thereof, sub-phthalocyanine and a derivative thereof, boron dipyrromethene (“BODIPY”) and a derivative thereof, but is not limited thereto.

Herein, the p-type and n-type semiconductor materials are respectively illustrated in an exemplary embodiment, where the active layer 130 absorbs light of a green wavelength region, but are not limited thereto. In an alternative exemplary embodiment, the active layer 130 may selectively absorb light of a blue wavelength region or light of a red wavelength region.

The active layer 130 may have a single layer structure or a multilayer structure. The active layer 130 may include, for example, an intrinsic layer (“I layer”), a p-type layer/I layer, an I layer/n-type layer, a p-type layer/I layer/n-type layer, a p-type layer/n-type layer, and the like.

The I layer may include the p-type semiconductor material and the n-type semiconductor material in a ratio of about 1:100 to about 100:1. In such an embodiment, the p-type semiconductor material and the n-type semiconductor material may be included in the I layer with a composition ratio ranging from about 1:50 to about 50:1, e.g., about 1:10 to about 10:1, or about 1:1. When the p-type and n-type semiconductor materials have a composition ratio of one of the ranges described above, an exciton may be effectively produced, and a pn junction may be effectively formed.

The p-type layer may include the p-type semiconductor material, and the n-type layer may include the n-type semiconductor material.

The active layer 130 may have a thickness in a range of about 1 nm to about 500 nm, e.g., in a range of about 5 nm to about 300 nm. When the active layer 130 has a thickness in such ranges described above, the active layer may effectively absorb light, effectively separate holes from electrons, and transport electrons, thereby effectively improving photoelectric conversion efficiency.

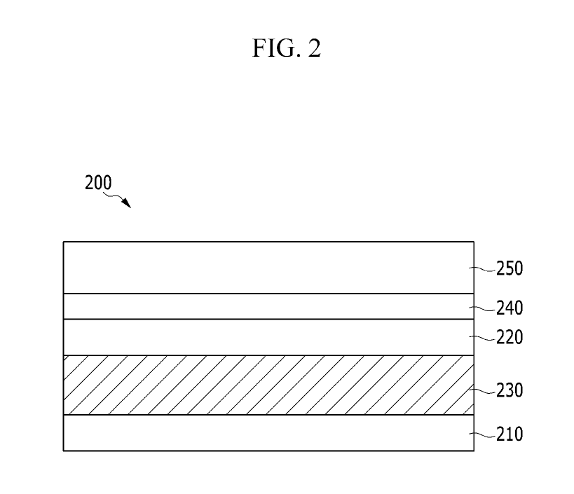

Referring to FIG. 2, an alternative exemplary embodiment of an organic photoelectronic device according to the invention will be described.

FIG. 2 is a cross-sectional view of an alternative exemplary embodiment of an organic photoelectronic device according to the invention.

Referring to FIG. 2, an exemplary embodiment of an organic photoelectronic device 200 includes a first light-transmitting electrode 220, a second light-transmitting electrode 210 disposed opposite to the first light-transmitting electrode, an active layer 230 disposed between the first light-transmitting electrode 220 and the second light-transmitting electrode 210 and including organic light-absorbing material, a UV blocking layer 240 disposed on the first light-transmitting electrode 220, and a thin film encapsulant 250 disposed on the UV blocking layer 240.

According to an exemplary embodiment, the first light-transmitting electrode 220 may define a front side electrode positioned at a light-incident side, and the second light-transmitting electrode 210 may define a back side electrode facing the front side electrode. One of the first light-transmitting electrode 220 and the second light-transmitting electrode 210 is an anode, and the other of the first light-transmitting electrode 220 and the second light-transmitting electrode 210 is a cathode.

In such an embodiment, the first light-transmitting electrode 220 and a second light-transmitting electrode 210 are substantially the same as those in exemplary embodiments described above with reference to FIG. 1, and any repetitive detail descriptions thereof will be omitted or simplified.

The active layer 230 may be a layer where p-type and n-type semiconductor materials form a pn flat junction or a bulk heterojunction. The active layer 230 may have a single-layer structure or a multilayer structure. The active layer 230 may receive light entering through the first light-transmitting electrode 220, produce an exciton, and then separate the exciton into a hole and an electron.

In an exemplary embodiment, the active layer 230 may include p-type and n-type semiconductor materials, which respectively absorb light of a green wavelength region.

In one exemplary embodiment, for example, the active layer 230 may include a p-type semiconductor material having a maximum absorption peak in a wavelength region of about 500 nm to 600 nm, and a n-type semiconductor material having a maximum absorption peak in a wavelength region of about 500 nm to 600 nm.

In such an embodiment, the hole moves toward the anode and the electron moves toward the cathode in the active layer 230, such that a current flows through the organic photoelectronic device.

In such an embodiment, the other features of the active layer 230 are substantially the same as those in the exemplary embodiment describe above with reference to FIG. 1, and any repetitive detail description thereof will be omitted.

UV blocking layer 240 may include a UV absorbing layer or a UV reflecting layer. Other features of the UV absorbing layer or the UV reflecting layer in such an embodiment are substantially the same as those in the exemplary embodiment described above with reference to FIG. 1, and any repetitive detail description thereof will be omitted.

In an exemplary embodiment, the thin film encapsulant 250 is disposed on the UV blocking layer 240.

The thin film encapsulant 250 protects the organic photoelectronic device from moisture, gas, and the like of the exterior. The thin film encapsulant 250 may include an organic or inorganic material, and may include at least one selected from materials that are transparent, heat resistant, capable of preventing moisture or gas from penetrating from outside, and not affecting any substantially adverse effect on the organic photoelectronic device.

In one exemplary embodiment, for example, thin film encapsulant 250 may be formed by sputtering or ALD using a transparent inorganic oxide on the UV blocking layer 240. The transparent inorganic oxide may be substantially the same material as those used for preparing the UV blocking layer 240. In such an embodiment, thin film encapsulant 250 may include an inorganic oxide material, such as, AlOx, SiNx, SiOx, SiON, and the like, for example.

In an exemplary embodiment, as described above, the materials used for preparing a thin film encapsulant may also be used for preparing a UV blocking layer. Accordingly, in an exemplary embodiment, where the organic photoelectronic device including such a UV blocking layer may also have an effect of having a thin film encapsulant, as well as having UV reflection effects. Therefore, in such an embodiment, a thin film encapsulant may be obtained.

In an exemplary embodiment, thin film encapsulant 250 may be formed by depositing an organic compound by heat sputtering on UV blocking layer. The organic compound used to from the thin film encapsulant 250 may be selected from any compounds known in the field.

The thin film encapsulant 250 may have a thickness in a range of about 50 nm to about 1000 nm.

In such an embodiment, where the thin film encapsulant 250 has a thickness in the range of about 50 nm to about 1000 nm, the thin film encapsulant 250 may effectively protect the organic photoelectronic device from moisture and gas of the exterior.

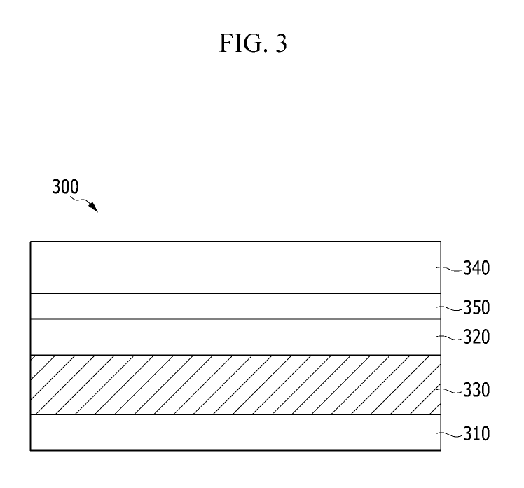

Hereinafter, another alternative exemplary embodiment of an organic photoelectronic device according to the invention will be described referring to FIG. 3.

FIG. 3 is a cross-sectional view of another alternative exemplary embodiment of an organic photoelectronic device according to the invention.

Referring to FIG. 3, an exemplary embodiment of an organic photoelectronic device 300 according to invention includes a first light-transmitting electrode 320, a second light-transmitting electrode 310 disposed opposite to the first light-transmitting electrode 320, an active layer 330 disposed between the first light-transmitting electrode 320 and the second light-transmitting electrode 310 and including an organic light-absorbing material, a thin film encapsulant 350 disposed on the first light-transmitting electrode 320, and a UV blocking layer 340 disposed on the thin film encapsulant 350.

According to an exemplary embodiment, as shown in FIG. 3, the first light-transmitting electrode 320 may be a front side electrode positioned at a light-incident side, and the second light-transmitting electrode 310 may be a back side electrode opposite to the front side electrode. One of the first light-transmitting electrode 320 and the second light-transmitting electrode 310 is an anode, and the other of the first light-transmitting electrode 320 and the second light-transmitting electrode 310 is a cathode.

In such an embodiment, the features of the first light-transmitting electrode 320 and a second light-transmitting electrode 310 are substantially the same as those in the exemplary embodiment described above with reference to FIG. 1, and any repetitive detail description thereof will be omitted.

In such an embodiment, the active layer 330 may be a layer where p-type and n-type semiconductor materials form a pn flat junction or a bulk heterojunction. The active layer 330 may have a single-layer structure or a multilayer structure. The active layer 330 may receive light entering through the first light-transmitting electrode 320, produce an exciton, and then separate the exciton into a hole and an electron.

When the hole moves toward the anode and the electron moves toward the cathode in the active layer 330, a current flows through the organic photoelectronic device.

In an exemplary embodiment, the active layer 330 may include p-type and n-type semiconductor materials, which respectively absorb light of a green wavelength region.

In one exemplary embodiment, for example, the active layer 330 may include p-type semiconductor material having a maximum absorption peak in a wavelength region of about 500 nm to 600 nm, and n-type semiconductor material having a maximum absorption peak in a wavelength region of about 500 nm to 600 nm.

In such an embodiment, other features of the active layer 330 are substantially the same as those in the exemplary embodiments described above with reference to FIG. 1, and any repetitive detail description thereof will be omitted.

In an exemplary embodiment, as shown in FIG. 3, the thin film encapsulant 350 is disposed between the first light-transmitting electrode 320 and the UV blocking layer 340.

As described above, the thin film encapsulant 350 protects the organic photoelectronic device from moisture or gas of the exterior, and the thin film encapsulant 350 may be disposed on the UV blocking layer as shown in FIG. 2, or may be disposed between the first light-transmitting electrode 350 and the UV blocking layer 340 as shown in FIG. 3.

In one exemplary embodiment, for example, the UV blocking layer 340 may have a light transmittance equal to or less than about 50% with respect to the light have a wavelength less than or equal to about 380 nm.

In such an embodiment, the UV blocking layer 340 may include a UV absorbing layer or a UV reflecting layer. In such an embodiment, the features of the UV absorbing layer or the UV reflecting layer are substantially the same as those in the exemplary embodiment described above with reference to FIG. 1, and any repetitive detail description thereof will be omitted.

In an exemplary embodiment, the organic photoelectronic device (100, 200 or 300) may further include a charge auxiliary layer (not shown) disposed between the light-transmitting electrode and the active layer. The charge auxiliary layer may facilitate the transfer of holes and electrons separated from the active layer, to increase efficiency. The charge auxiliary layer may include at least one of a hole injection layer (“HIL”) for facilitating hole injection, a hole transport layer (“HTL”) for facilitating hole transport, an electron blocking layer (“EBL”) for preventing electron transport, an electron injection layer (“EIL”) for facilitating electron injection, an electron transport layer (“ETL”) for facilitating electron transport, and a hole blocking layer (“HBL”) for preventing hole transport.

The HTL may include at least one selected from, for example, poly(3,4-ethylenedioxythiophene):poly(styrenesulfonate) (“PEDOT:PSS”), polyarylamine, poly(N-vinylcarbazole), polyaniline, polypyrrole, N,N,N′,N′-tetrakis(4-methoxyphenyl)-benzidine (“TPD”), 4-bis[N-(1-naphthyl)-N-phenyl-amino]biphenyl (“α-NPD”), 4,4′,4″-tris[phenyl(m-tolyl)amino]triphenylamine (“m-MTDATA”), 4,4′,4″-tris(N-carbazolyl)-triphenylamine (“TCTA”), 1,4,5,8,9,11-hexaazatriphenylenehexacarbonitrile (“HATCN”), 1,1′-bis(4-bis(4-methyl-phenyl)amino-phenyl)-cyclohexane (“TAPC”), and a combination thereof, but is not limited thereto.

The EBL may include at least one selected from, for example, PEDOT:PSS, polyarylamine, poly(N-vinylcarbazole), polyaniline, polypyrrole, TPD, α-NPD, m-MTDATA, TCTA, HATCN, TAPC, and a combination thereof, but is not limited thereto.

The ETL may include at least one selected from, for example, 1,4,5,8-naphthalene-tetracarboxylic dianhydride (“NTCDA”), bathocuproine (“BCP”), LiF, Alq₃, Gaq₃, Inq₃, Znq₂, Zn(BTZ)₂, BeBq₂, and a combination thereof, but is not limited thereto.

The HBL may include at least one selected from, for example, NTCDA, BCP, LiF, Alq₃, Gaq₃, Inq₃, Znq₂, Zn(BTZ)₂, BeBq₂, and a combination thereof, but is not limited thereto.

The organic photoelectronic device may include an active layer that receives light entering through a light-transmitting electrode, produces an exciton, and then separates the exciton into a hole and an electron. In such an embodiment, when the hole moves toward the anode and the electron moves toward the cathode, a current flows through the organic photoelectronic device.

Hereinafter, exemplary embodiments of an image sensor including the organic photoelectronic device will be described referring to drawings. In an exemplary embodiment, where an image sensor is an organic complementary metal-oxide-semiconductor (“CMOS”) image sensor will be described for convenience of description, but the image sensor is not limited thereto.

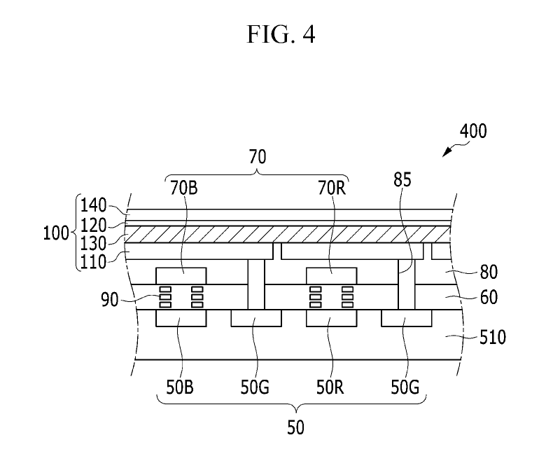

FIG. 4 is a cross-sectional view of an exemplary embodiment of an organic CMOS image sensor according to invention.

FIG. 4 shows an exemplary embodiment, where blue, green and red pixels are disposed adjacent to one another, but not being limited thereto. Hereinafter, a constituent element including ‘B’ in the reference symbol refers to a constituent element included in the blue pixel, a constituent element including ‘G’ refers to a constituent element included in the green pixel, and a constituent element including ‘R’ in the reference symbol refers to a constituent element included in the red pixel.

Referring to FIG. 4, an organic CMOS image sensor 400 includes a semiconductor substrate 510 integrated with a photo-sensing device 50 and a transmission transistor (not shown), a lower insulation layer 60, a color filter 70, an upper insulation layer 80, and an organic photoelectronic device 100.

The semiconductor substrate 510 may be a silicon substrate, and may be integrated with the photo-sensing device 50 and the transmission transistor (not shown). The photo-sensing device 50 may be a photodiode, or may store charges generated in the organic photoelectronic device 100. The photo-sensing device 50 and the transmission transistor may be integrated in each pixel, and as shown in FIG. 4, the photo-sensing device 50 includes a blue pixel photo-sensing device 50B, a green pixel photo-sensing device 50G, and a red pixel photo-sensing device 50R. The photo-sensing device 50 senses light, and the information sensed by the photo-sensing device 50 is transferred through the transmission transistor.

In such an embodiment, metal wires 90 and pads (not shown) may be disposed on the semiconductor substrate 510. In such an embodiment, the metal wires 90 and pads may be made of a metal having low resistivity, for example, aluminum (Al), copper (Cu), silver (Ag), and alloys thereof to decrease signal delay, but is not limited thereto.

The lower insulation layer 60 may be disposed on the metal wires 90 and the pads. The lower insulation layer 60 may include, or be made of, an inorganic insulating material such as a silicon oxide and/or a silicon nitride, or a low dielectric constant (e.g., low K) material such as SiC, SiCOH, SiCO, and SiOF.

The lower insulation layer 60 may have a trench exposing each photo-sensing device 50B, 50G, and 50R of each pixel. The trench may be filled with fillers.

According to an exemplary embodiment, as shown in FIG. 4, the color filter 70 is disposed on the lower insulation layer 60. The color filter 70 includes a blue filter 70B in the blue pixel and a red filter 70R in the red pixel. In an exemplary embodiment, a green filter (not shown) may be further included.

According to an exemplary embodiment, the upper insulation layer 80 is disposed on the color filter 70. The upper insulation layer 80 eliminates a step caused by the color filters 70 and planarizes or contributes to smoothing a surface on which the organic photoelectronic device 100 is disposed. In an exemplary embodiment, a contact hole (not shown) exposing a pad, and a penetration hole 85 exposing the photo-sensing device 50G of a green pixel may be defined through the upper insulation layer 80 and lower insulation layer 60.

The organic photoelectronic device 100 is disposed on the upper insulation layer 80. In such an embodiment, the organic photoelectronic device 100 is substantially the same as the exemplary embodiments of the organic photoelectronic device described above. The organic photoelectronic device 100 includes the first light-transmitting electrode 120, the active layer 130, the second light-transmitting electrode 110, and the UV blocking layer 140, as described above.

According to an exemplary embodiment, the active layer 130 includes a p-type semiconductor material and an n-type semiconductor material that selectively absorb light in a green wavelength region as described above, and that photo-electrically convert the absorbed light.

When light enters the organic photoelectronic device, the light first passes through the UV blocking layer 140 to reduce or remove UV light, and the light free of or having reduced UV light passes through the first light-transmitting electrode 120 to the active layer 130. The light in a green wavelength region may be mainly absorbed and photo-electrically converted in the active layer 130, while the light in the rest of the wavelength regions passes through the second light-transmitting electrode 110 and may be sensed in a photo-sensing device 50.

The image sensor 400 may further include a micro lens (not shown) defined above the UV blocking layer 140. The micro lens may be formed by a process radiating UV light, and the image sensor 400 including UV blocking layer 140 may protect the active layer 130 in the organic photoelectronic device 100 from the UV light radiated in the process of fabricating the micro lens.

Prior to fabricating the micro lens, a flat layer (not shown) may further be formed on the upper surface of the image sensor 400.

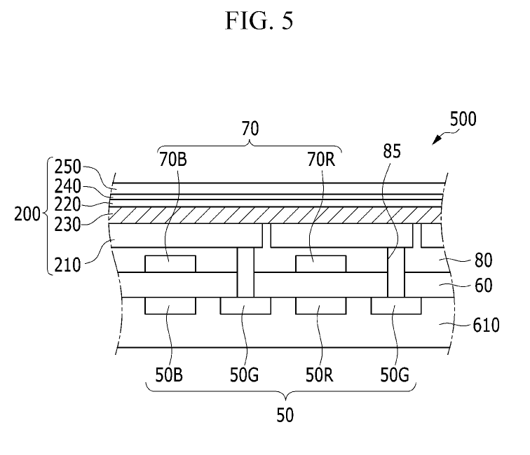

FIG. 5 is cross-sectional view of an alternative exemplary embodiment of an organic CMOS image sensor according to invention.

Referring to FIG. 5, an exemplary embodiment of an organic CMOS image sensor 500 includes a semiconductor substrate 610 integrated with a photo-sensing device 50 and a transmission transistor (not shown), a lower insulation layer 60, a color filter 70, and an upper insulation layer 80, similarly to the exemplary embodiments described above with reference to FIG. 4. In such an embodiment, the organic CMOS image sensor 500 includes the organic photoelectronic device 200 further including the thin film encapsulant 250 disposed on the UV blocking layer 240, as shown in FIGS. 2 and 5.

The image sensor 500 may further include a micro lens (not shown) disposed above the thin film encapsulant 250 that is disposed on the UV blocking layer 240. The micro lens may be formed by a process radiating UV light, and the image sensor 500 including UV blocking layer 240 may protect the active layer 230 in the organic photoelectronic device 200 from the UV light radiated in the process of fabricating the micro lens.

Prior to fabricating a micro lens, a flat layer (not shown) may further be formed on the upper surface of the image sensor 500.

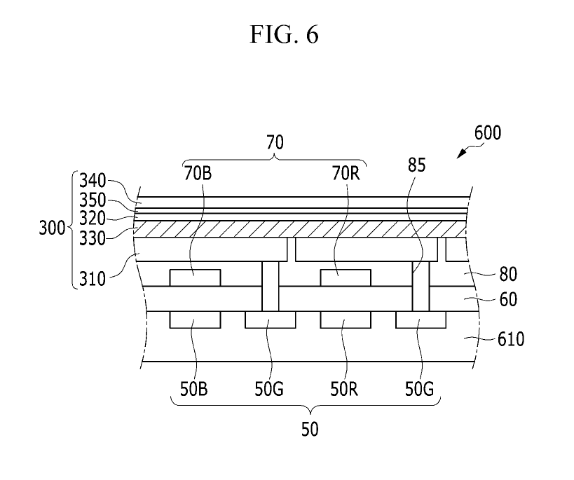

FIG. 6 is cross-sectional view of another alternative exemplary embodiment of an organic CMOS image sensor according to invention.

Referring to FIG. 6, an exemplary embodiment of an organic CMOS image sensor 600 includes a semiconductor substrate 610 integrated with a photo-sensing device 50 and a transmission transistor (not shown), a lower insulation layer 60, a color filter 70, and an upper insulation layer 80. The organic CMOS image sensor 600 includes an organic photoelectronic device 300 including thin film encapsulant 350 disposed between the first light-transmitting electrode 320 and UV blocking layer 340, as shown in FIGS. 3 and 6.

The image sensor 600 may further include a micro lens (not shown) disposed above the UV blocking layer 340. The micro lens may be formed by a process radiating UV light, and the image sensor 600 including UV blocking layer 340 may protect the active layer 330 in the organic photoelectronic device 300 from the UV light radiated in the process of fabricating the micro lens.

Prior to fabricating a micro lens, a flat layer (not shown) may further be formed on the upper surface of the image sensor 600.

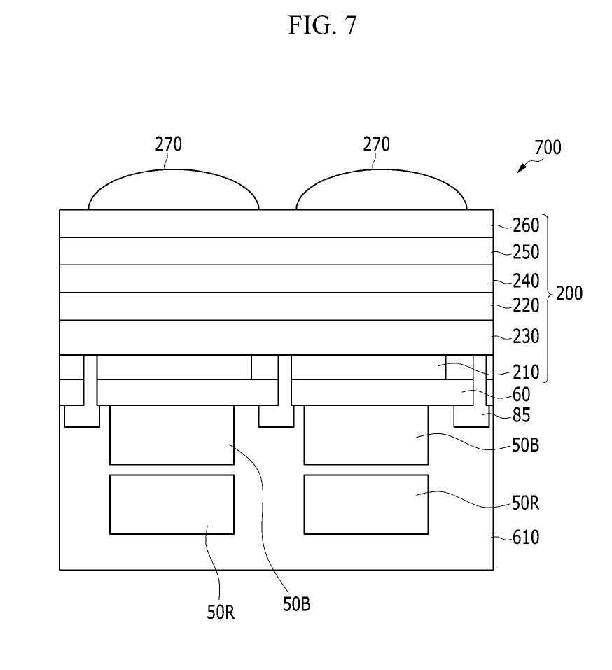

FIG. 7 is cross-sectional view of yet another alternative exemplary embodiment of an organic CMOS image sensor according to invention.

Referring to FIG. 7, an exemplary embodiment of an organic CMOS image sensor 700 includes a semiconductor substrate 610 integrated with a photo-sensing device 50 and a transmission transistor (not shown), a lower insulation layer 60, and an organic photoelectronic device on the insulation layer 60. In such an embodiment, the organic CMOS image sensor 700 includes the organic photoelectronic device 200 including the thin film encapsulant 250 disposed on the UV blocking layer 240.

In an exemplary embodiment, as shown in FIG. 7, color filters for blue pixel and red pixel may be omitted, and the red pixel 50R is disposed below the blue pixel 50B in the semiconductor substrate 610. In such an embodiment, the blue pixel 50B may be a silicon photodiode for sensing light in a blue wavelength region and the red pixel 50R may be a silicon photodiode for sensing light in a red wavelength region.

The blue pixel 50B and the red pixel 50R includes the silicon photodiodes for sensing blue light and red light, respectively, and the image sensor 700 shown in FIG. 7 is substantially the same as the image sensor 500 shown in FIG. 5, except that the red pixel 50R is positioned below the blue pixel 50B.

In an exemplary embodiment, as shown in FIG. 7, the organic CMOS image sensor may further include micro lenses 270 disposed on a flat layer 260, which is disposed on the thin film encapsulant 250 of the organic photoelectronic device 200.

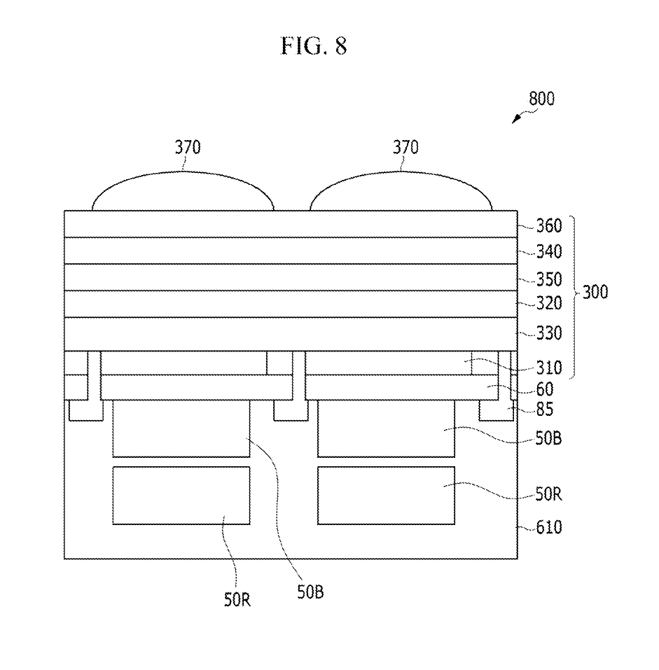

FIG. 8 is cross-sectional view of yet another alternative exemplary embodiment of an organic CMOS image sensor according to invention.

The organic CMOS image sensor 800 shown in FIG. 8 is substantially with the same as the organic CMOS image sensor shown in FIG. 7, except that the image sensor 300 includes the organic photoelectronic device 300 including the thin film encapsulant 350 between the UV blocking layer 340 and the first light-transmitting electrode 320 and a flat layer 360 disposed on the UV blocking layer 340, and that micro lenses 370 are disposed on the flat layer 360.

In such an embodiment, the other features of the organic CMOS image sensor 800 are substantially the same as the exemplary embodiments of the organic CMOS image sensor described above with reference to FIG. 7, and any repetitive detailed description thereof will be omitted.

Hereinafter, exemplary embodiments of the invention will be described in greater detail with reference to examples. However, exemplary embodiments of the invention are not limited thereto.

### EXAMPLES

### Example 1

### Manufacture of UV Reflecting Layer

ZrO₂ having refractive index of about 2.1 and SiO₂ having refractive index of about 1.5 are alternately disposed, e.g., stacked or laminated, to form a plurality of laminated structures by using atomic layer chemical vapor deposition (“ALCVD”) and plasma-enhanced chemical vapor deposition (“PECVD”), respectively, by changing total number of layers and thicknesses of the laminated structures to simulate transmittance of UV light therethrough.

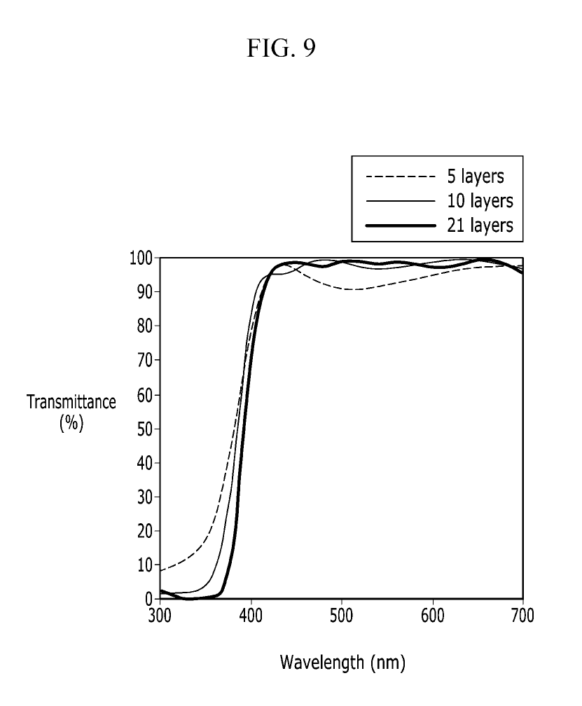

Particularly, ZrO₂ and SiO₂ are alternately laminated to form laminated structures having 5 layers, 10 layers, and 21 layers, respectively. The laminated structure having 5 layers has a thickness of about 171 nm, and the laminated structure having 10 layers has a thickness of about 394 nm. FIG. 9 shows graphs of the transmittance of light of such laminated structures.

As shown from FIG. 9, by alternately laminating two materials having different refractive indexes, the greater the number of layers and the thicker the thickness of the laminated structure are, the less the transmittance of light having a wavelength less than or equal to about 380 nm.

### Examples 2 and 3

### Manufacture of Organic Photoelectronic Devices having UV Absorbing Layer

A lower electrode that is about 150 nm-thick is formed by sputtering ITO on a glass substrate. Subsequently, an active layer is formed on the lower electrode by thermally evaporating a mixture of SubPc-Cl:C60 in a ratio of 1:1 to be 110 nm thick, an hole transfer layer is formed on the active layer by depositing MoOx to be 8 nm thick, and a 7 nm-thick upper electrode is formed on the hole transfer layer by sputtering ITO at a speed of 0.87 angstrom/second (A(s) for 1,384 seconds (DC: 300 W, chamber pressure: 2 mTorr, Ar: 30 sccm, O₂: 0.62 sccm), thereby manufacturing an organic photoelectronic device.

Further, a UV absorbing layer is formed on the upper electrode by thermally evaporating 4,4-Bis(2-benzoxazolyl)stilbene to be 120 nm (Example 2) or to be 240 nm (Example 3).

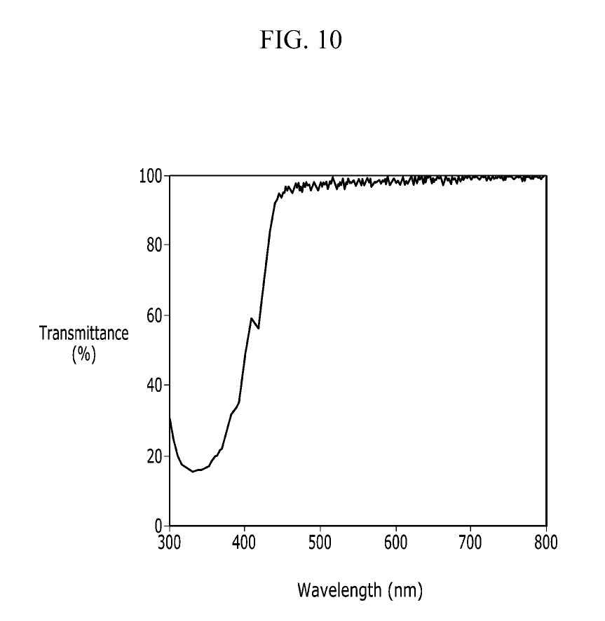

As shown in FIG. 10, 4,4-Bis(2-benzoxazolyl)stilbene is a UV absorber, the light absorbance of which at 365 nm is as much as about 80% when 4,4-Bis(2-benzoxazolyl)stilbene alone is prepared as a film having a thickness of 125 nm.

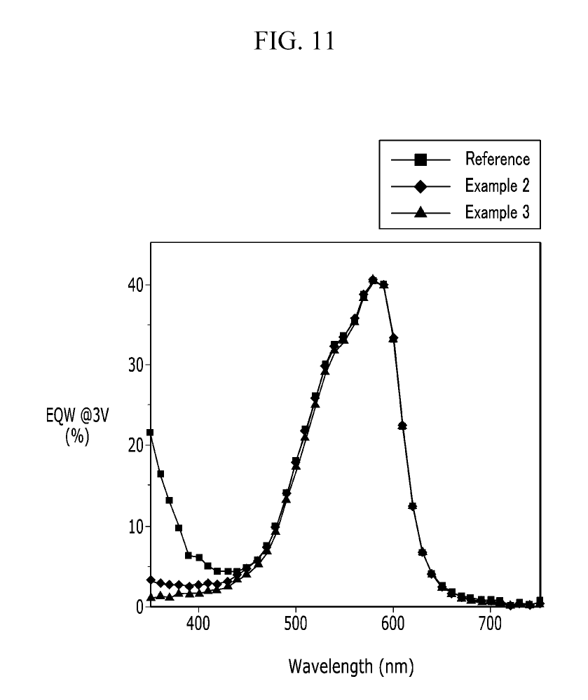

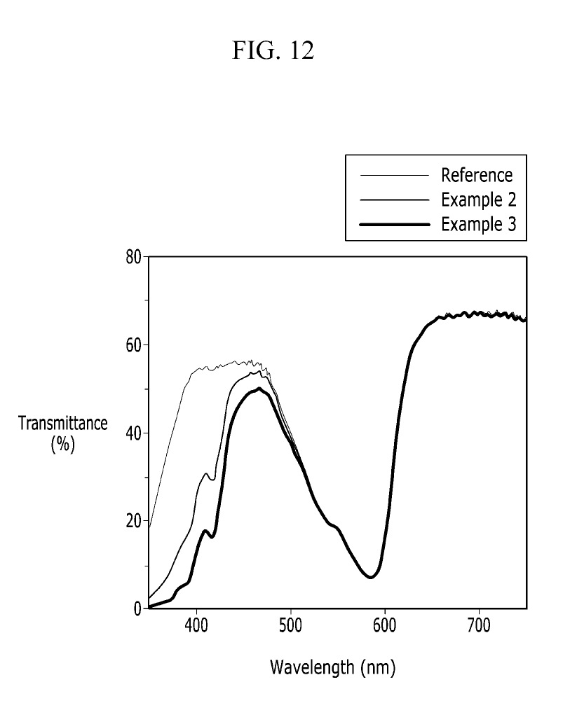

After encapsulating top of the manufactured organic photoelectronic devices with glass, EQE and transmittance of light versus wavelengths are measured and illustrated in FIGS. 11 and 12, respectively.

In FIGS. 11 and 12, the organic photoelectronic device without the UV absorbing layer is referred to as “Reference.”

EQE is measured by using incident photon-to-current efficiency (“IPCE”) measurement system (Oriel, USA). First, after the IPCE measurement system is calibrated by using a Si photodiode (Newport, USA), the organic photoelectronic devices according to Reference, and Examples 2 and 3 are mounted in the system, and external quantum efficiency of the organic photoelectronic devices in a wavelength ranging from about 300 nm to about 700 nm is measured. Herein, the bias is 3 volts (V).

The results are provided in FIGS. 11 and 12.

As shown from FIG. 11, the organic photoelectronic devices according to Examples 2 and 3 show similar EQE with that of Reference for a wavelength greater than or equal to about 450 nm, and show reduced EQE compared to the Reference for a wavelength less than or equal to about 450 nm, which means that the organic photoelectronic devices including the UV absorbing layer do not show substantial reduction of EQE.

Further, as shown from FIG. 12, the transmittance of light of the organic photoelectronic devices according to Examples 2 and 3 is less than about 20% for the wavelength less than or equal to about 380 nm, indicating that both Examples 2 and 3 may absorb about 80% or more UV light. On the contrary, the transmittance of light having the wavelength less than or equal to about 380 nm through the Reference is greater than 50%.

While the invention has been described in connection with exemplary embodiments, it is to be understood that the invention is not limited to the disclosed exemplary embodiments, but, on the contrary, is intended to cover various modifications and equivalent arrangements included within the spirit and scope of the appended claims.

What is claimed is:

1. An organic photoelectronic device, comprising:
a first light-transmitting electrode;
a second light-transmitting electrode opposite to the first light-transmitting electrode,
an active layer between the first light-transmitting electrode and the second light-transmitting electrode; and
a UV blocking layer on the first light-transmitting electrode,
wherein the UV blocking layer comprises at least one of a UV light absorbing layer and a UV reflecting layer,
the UV light absorbing layer comprises a layer comprising an organic material, and
the UV reflecting layer comprises a plurality of layers, wherein each of the plurality of layers comprises an organic material, an inorganic material or a combination thereof.

2. The organic photoelectronic device according to claim 1, wherein the UV blocking layer has a transmittance less than or equal to about 50% with respect to light having a wavelength less than or equal to about 380 nm.

3. The organic photoelectronic device according to claim 1, wherein
the UV blocking layer comprises the UV reflecting layer comprising the plurality of layers,
each of the plurality of layers comprises an inorganic oxide, and inorganic oxides of the plurality of layers are different from each other.

4. The organic photoelectronic device according to claim 3, wherein
the inorganic oxides of the plurality of layers have different refractive indices from each other, and
thicknesses of the plurality of layers are determined to allow the UV reflecting layer to have a transmittance greater than or equal to about 50% with respect to light having a wavelength less than or equal to about 380 nm.

5. The organic photoelectronic device according to claim 4, wherein the inorganic oxide has a refractive index in a range of about 1.4 to about 2.1.

6. The organic photoelectronic device according to claim 5, wherein
when the inorganic oxide of a layer of the plurality of layers has a refractive index of greater than or equal to about 1.7 and less than or equal to about 2.1, the layer has a thickness in a range of about 10 nm to about 100 nm, and
when the inorganic oxide of the layer has a refractive index of greater than or equal to about 1.4 and less than about 1.7, the layer has a thickness in a range of about 10 nm to about 100 nm.

7. The organic photoelectronic device according to claim 1, wherein the inorganic material, which reflects UV light, comprises ZrO₂, TiO₂, ZnS, SiO₂, SiON, Al₂O₃ or a combination thereof.

8. The organic photoelectronic device according to claim 1, wherein the organic material, which absorbs UV light, comprises an organic compound having a UV extinction coefficient of greater than or equal to about 0.2.

9. The organic photoelectronic device according to claim 8, wherein the organic compound having the UV extinction coefficient of greater than or equal to about 0.2 comprises at least one selected from stilbene derivatives, phenylenevinylene derivatives, bezoxazole derivatives, bezotriazole derivatives, benzophenone derivatives and triazine derivatives.

10. The organic photoelectronic device according to claim 1, further comprising:
a thin film encapsulator on the UV blocking layer or between the UV blocking layer and the first light-transmitting electrode.

11. The organic photoelectronic device according to claim 1, wherein each of the first light-transmitting electrode and the second light-transmitting electrode comprises at least one selected from indium tin oxide, indium zinc oxide, tin oxide, aluminum tin oxide, aluminum zinc oxide, and fluorine-doped tin oxide.

12. The organic photoelectronic device according to claim 1, wherein
the first light-transmitting electrode has a thickness in a range of about 1 nm to about 100 nm, and
the second light-transmitting electrode has a thickness in a range of about 1 nm to about 200 nm.

13. The organic photoelectronic device according to claim 1, wherein the active layer selectively absorbs light in a green wavelength region.

14. The organic photoelectronic device according to claim 13, wherein the active layer comprises:
p-type semiconductor material having a maximum absorption peak in a wavelength region of about 500 nm to about 600 nm; and
n-type semiconductor material having a maximum absorption peak in the wavelength region of about 500 nm to about 600 nm.

15. An image sensor comprising the organic photoelectronic device according to claim 1.

16. The image sensor according to claim 15, further comprising:
a micro lens on the UV blocking layer of the organic photoelectronic device.

17. An image sensor comprising:
a green pixel comprising the organic photoelectronic device according to claim 13 and a green photo-sensing device electrically connected to the organic photoelectronic device,
a red pixel comprising a red color filter and a red photo-sensing silicon diode, and
a blue pixel comprising a blue color filter and a blue photo-sensing silicon diode,
wherein
the red photo-sensing silicon diode and the blue photo-sensing silicon diode are integrated in a semiconductor substrate disposed below the green pixel, and
the red color filter and the blue color filter are disposed between the semiconductor substrate and the green pixel, and to correspond to positions of the red photo-sensing silicon diode and the blue photo-sensing silicon diode, respectively.

18. The image sensor according to claim 18, further comprising:
a micro lens disposed on the green pixel.

19. An image sensor comprising:
a green pixel comprising the organic photoelectronic device according to claim 13 and a green photo-sensing device electrically connected to the organic photoelectronic device;
a red pixel comprising a red photo-sensing silicon diode; and
a blue pixel comprising a blue photo-sensing silicon diode,
wherein
the red photo-sensing silicon diode and the blue photo-sensing silicon diode are integrated in a semiconductor substrate disposed below the green pixel, and
the red photo-sensing silicon diode is disposed below the blue photo-sensing silicon diode.

20. The image sensor according to claim 19, further comprising:
a micro lens disposed on the green pixel.
